(19) United States
(12) Patent Application Publication
(10) Pub. No.: US 2025/0348641 A1
(43) Pub. Date: Nov. 13, 2025

(54) TRAINING A MACHINE LEARNING MODEL TO GENERATE MRC AND PROCESS AWARE MASK PATTERN

(71) Applicant: ASML NETHERLANDS B.V., Veldhoven (NL)

(72) Inventor: Ayman HAMOUDA, Milpitas, CA (US)

(73) Assignee: ASML NETHERLANDS B.V., Veldhoven (NL)

(21) Appl. No.: 18/867,761

(22) PCT Filed: Jul. 14, 2023
(86) PCT No.: PCT/EP2023/069735

§ 371 Date: Nov. 20, 2024

Related U.S. Application Data
(60) Provisional application No. 63/393,024, filed on Jul. 28, 2022.

(51) Int. Cl. G06F 30/32; G06F 30/27

(52) U.S. Cl. CPC G06F 30/32; G06F 30/27

(57) ABSTRACT

Methods and systems for training a prediction model to predict a mask image in which mask rule check (MRC) violations or process violations (e.g., edge placement error, sub-resolution assist feature (SRAF) printing) are minimized or eliminated. The prediction model is trained based on a loss function that is indicative of (a) a difference between the predicted mask image and a reference image, and (b) at least one selected from: an MRC evaluation of the predicted mask image or an evaluation of a simulated image of the predicted mask image.

### CROSS-REFERENCE TO RELATED APPLICATIONS

This application claims priority of U.S. application 63/393,024 which was filed on Jul. 28, 2022 and which is incorporated herein in its entirety by reference.

### TECHNICAL FIELD

The description herein relates to designing photolithography masks to be employed in semiconductor manufacturing, and more specifically to training machine learning models to generate a mask pattern.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g. comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, lithography is a central step in the manufacturing of ICs, where patterns formed on substrates define functional elements of the ICs, such as microprocessors, memory chips etc. Similar lithographic techniques are also used in the formation of flat panel displays, micro-electromechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### BRIEF SUMMARY

In some embodiments, there is provided a non-transitory computer readable medium having instructions that, when executed by a computer, cause the computer to execute a method for training a machine learning model to generate a mask image to be used for printing a target layout on a substrate. The method includes: inputting a target image to a neural network, the target image associated with a target layout to be printed on a substrate, wherein the neural network is configured to receive a reference image, the reference image corresponding to an optical proximity correction (OPC) mask image of the target image; generating, using the neural network, a predicted mask image representing a mask pattern to be used for printing the target layout on a substrate; computing a loss function that is indicative of (a) a difference between the predicted mask image and the reference image, and (b) at least one of an MRC evaluation of the predicted mask image or an evaluation of a first simulated image of the predicted mask image; and modifying the neural network based on the loss function.

In some embodiments, there is provided a non-transitory computer-readable medium having instructions that, when executed by a computer, cause the computer to execute a method for training a machine learning model to generate a mask image to be used for printing a target layout on a substrate. The method includes: inputting a set of target images and a set of reference images as training data to a neural network, wherein a target image of the set of target images includes a target layout to be printed on a substrate, and wherein a reference image of the set of reference images corresponds to an optical proximity correction (OPC) mask image of the target image; and training, based on the training data, the neural network to generate a predicted mask image such that a loss function that is indicative of (a) a difference between the predicted mask image and the reference image, and (b) an MRC cost associated with an MRC evaluation of the predicted mask image is minimized.

In some embodiments, there is provided a non-transitory computer-readable medium having instructions that, when executed by a computer, cause the computer to execute a method for training a machine learning model to generate a mask image to be used for printing a target layout on a substrate. The method includes: inputting a set of target images and a set of reference images as training data to a neural network, wherein a target image of the set of target images includes a target layout to be printed on a substrate, and wherein a reference image of the set of reference images corresponds to an optical proximity correction (OPC) mask image of the target image; and training, based on the training data, the neural network to generate a predicted mask image such that a loss function that is indicative of (a) a difference between the predicted mask image and the reference image, and (b) a simulation cost associated with a first simulated image of the predicted mask image is minimized.

In some embodiments, there is provided a method for training a machine learning model to generate a mask image to be used for printing a target layout on a substrate. The method includes: inputting a target image to a neural network, the target image associated with a target layout to be printed on a substrate, wherein the neural network is configured to receive a reference image, the reference image corresponding to an optical proximity correction (OPC) mask image of the target image; generating, using the neural network, a predicted mask image representing a mask pattern to be used for printing the target layout on a substrate; computing a loss function that is indicative of (a) a difference between the predicted mask image and the reference image, and (b) at least one of an MRC evaluation of the predicted mask image or an evaluation of a first simulated image of the predicted mask image; and modifying the neural network based on the loss function.

In some embodiments, there is provided an apparatus for training a machine learning model to generate a mask image to be used for printing a target layout on a substrate. The apparatus includes: a memory storing a set of instructions; and a processor configured to execute the set of instructions to cause the apparatus to perform a method of: inputting a target image to a neural network, the target image associated with a target layout to be printed on a substrate, wherein the neural network is configured to receive a reference image, the reference image corresponding to an optical proximity correction (OPC) mask image of the target image; generating, using the neural network, a predicted mask image representing a mask pattern to be used for printing the target layout on a substrate; computing a loss function that is indicative of (a) a difference between the predicted mask image and the reference image, and (b) at least one of an MRC evaluation of the predicted mask image or an evaluation of a first simulated image of the predicted mask image; and modifying the neural network based on the loss function.

### BRIEF DESCRIPTION OF THE DRAWINGS

FIG. 1 is a block diagram of various subsystems of a lithography system, consistent with various embodiments.

FIG. 2 shows a flow for a lithographic process or patterning simulation method, consistent with various embodiments.

FIG. 3 is a block diagram of a system for generating a mask pattern from a target layout using a prediction model, consistent with various embodiments.

FIG. 4 is a block diagram of a system for training a mask generator as an MRC aware or process aware mask generator, consistent with various embodiments.

FIG. 5 is a flow diagram of a method for training the mask generator as an MRC aware or process aware mask generator, consistent with various embodiments.

FIG. 6 is a flow diagram of a method for determining a mask rule compliance (MRC) loss, consistent with various embodiments.

FIG. 7 is a flow diagram of a method for determining a first simulation loss, consistent with various embodiments.

FIG. 8 is a flow diagram of a method for determining a second simulation loss, consistent with various embodiments.

FIG. 9 shows an example neural network 900 used to implement the mask generator 350, consistent with various embodiments.

FIG. 10 is a block diagram of an example computer system, according to an embodiment of the present disclosure.

### DETAILED DESCRIPTION

In lithography, to print a target pattern (also often referred to as “design layout” or “design” or “target layout”) on a substrate, a pattern of a patterning device (e.g., a “mask pattern” of a mask) is projected onto a layer of resist provided on a substrate (e.g., a wafer). The mask pattern may be projected onto one or more dies of the substrate. In some embodiments, the design layout or portions of the design layout are used for designing the mask to be employed in the semiconductor manufacturing. Generating a mask design (also referred to as a “mask pattern”) includes determining mask features based on mask optimization simulations. Some techniques use predictive models (e.g., a machine learning (ML) model such as a neural network) to predict a mask pattern from a target pattern. For example, the ML model is trained using a set of target images having a target pattern, and a corresponding set of mask images having a mask pattern as ground truth images, to generate a mask image. The ML model may learn a transfer function from the target pattern to the mask pattern by focusing on a faithful reconstruction of the ground truth image. However, conventional ML models may have some drawbacks. For example, conventional ML models are not guided by optical proximity correction (OPC) applications, and therefore, may not be aware of various metrics such as mask rule check or mask rule compliance (MRC) rules or other process simulation related metrics (e.g., edge placement error (EPE), sub-resolution assist feature (SRAF) or other issues). This disconnection could potentially result in less useful and stable solutions. Also, in some situations, critical prediction errors could arise from a very slight deviation from the ground truth and thus are ignored by the ML model. Some ML models may be configured to consider one or more of the above metrics in predicting a mask image, but even those ML model have some drawbacks. For example, the ML models may not be trained using supervised learning paradigm, that is, they may not be guided by ground truth images for generating the mask images. While they may accept target images as input, they do not generate a mask image, but a mask layout-which are polygons, as an output. That is, the conventional ML models do not operate in an image-to-image domain, thus may require additional image processing steps to generate various images in order to determine the metrics and train the ML model, thereby consuming significant amount of computing resources.

Disclosed herein is a mechanism for improving prediction of a mask pattern, for example, having curvilinear mask features, from a target layout using an MRC aware or process aware prediction model. The prediction model is configured to predict a mask image (e.g., of a mask pattern) from a target image (e.g., of a target layout). The prediction model may be trained based on a loss function (or cost function) that considers a first loss function, which is indicative of image reconstruction loss (e.g., a difference between a predicted mask image and a ground truth mask image) and a second loss function which is indicative of at least one of (a) an MRC loss or (b) a simulation loss (e.g., determined based on an evaluation of images simulated from the predicted mask image to determine process metrics such as EPE, SRAF printing, etc.). In some embodiments, the MRC loss is indicative of an MRC violation, which may be determined by performing an MRC evaluation of the predicted mask image to identify MRC violations and by scoring the identified MRC violations. In some embodiments, the simulation loss is indicative of a process metric (e.g., EPE), which may be determined based on a difference between simulated images (e.g., an aerial image, a resist image, or an etch image) of the predicted mask image and a ground truth mask image (e.g., near target features in the simulated images). In some embodiments, the simulation loss is also indicative of another process metric (e.g., SRAF printing) which may be determined by simulating an image (e.g., an aerial image, a resist image, or an etch image) of the predicted mask image, comparing pixel values of the simulated image to a threshold value, and scoring the pixels associated with values exceeding the threshold value. After the image reconstruction loss, and at least one of the MRC loss or simulation loss are determined, the prediction model may be modified (e.g., parameters of the prediction model) such that the loss function is minimized. The trained prediction model may then be used to predict a mask image in which the MRC violations or other process metrics such as EPE, SRAF printing are minimized or eliminated. The prediction model may include one or more of an ML model (e.g., a neural network), a statistical model, an analytics model, a rule-based model, or any other empirical model.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The term “optimizing” and “optimization” as used herein refers to or means adjusting a lithographic projection apparatus, a lithographic process, etc. such that results and/or processes of lithography have more desirable characteristics, such as higher accuracy of projection of a design layout on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Further, the lithographic projection apparatus may be of a type having two or more tables (e.g., two or more substrate table, a substrate table, and a measurement table, two or more patterning device tables, etc.). In such “multiple stage” devices a plurality of the multiple tables may be used in parallel, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above comprises, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. One or more of the design rule limitations may be referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

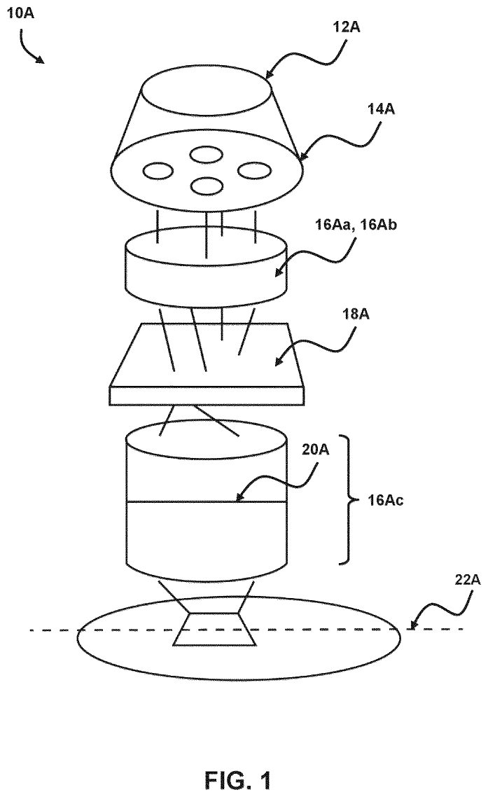

As a brief introduction, FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which define the partial coherence (denoted as sigma) and which may include optics 14A, 16Aa and 16Ab that shape radiation from the source 12A; a patterning device 14A; and transmission optics 16Ac that project an image of the patterning device pattern onto a substrate plane-22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), n is the Index of Refraction of the media between the last element of projection optics and the substrate, and Θₘₐₓ is the largest angle of the beam exiting from the projection optics that can still impinge on the substrate plane 22A. The radiation from the radiation source 12A may not necessarily be at a single wavelength. Instead, the radiation may be at a range of different wavelengths. The range of different wavelengths may be characterized by a quantity called “imaging bandwidth,” “source bandwidth” or simply “bandwidth,” which are used interchangeably herein. A small bandwidth may reduce the chromatic aberration and associated focus errors of the downstream components, including the optics (e.g., optics 14A, 16Aa and 16Ab) in the source, the patterning device, and the projection optics. However, that does not necessarily lead to a rule that the bandwidth should never be enlarged.

In an optimization process of a system, a figure of merit of the system can be represented as a cost function. The optimization process boils down to a process of finding a set of parameters (design variables) of the system that optimizes (e.g., minimizes or maximizes) the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations (i.e., worst deviation). The term “evaluation points” herein should be interpreted broadly to include any characteristics of the system. The design variables of the system can be confined to finite ranges and/or be interdependent due to practicalities of implementations of the system. In the case of a lithographic projection apparatus, the constraints are often associated with physical properties and characteristics of the hardware such as tunable ranges, and/or patterning device manufacturability design rules, and the evaluation points can include physical points on a resist image on a substrate, as well as non-physical characteristics such as dose and focus.

In a lithographic projection apparatus, a source provides illumination (i.e., radiation) to a patterning device and projection optics direct and shape the illumination, via the patterning device, onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Pat. No. 8,200,468, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device, and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

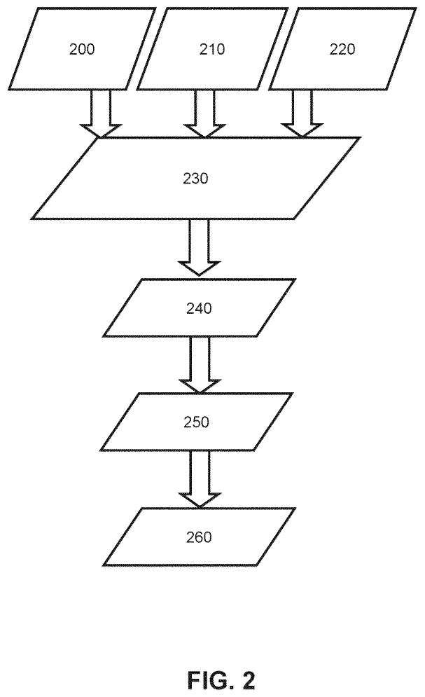

An exemplary flow chart for modelling and/or simulating parts of a patterning process is illustrated in FIG. 2. As will be appreciated, the models may represent a different patterning process and need not comprise all the models described below. A source model 200 represents optical characteristics (including radiation intensity distribution, bandwidth and/or phase distribution) of the illumination of a patterning device. The source model 200 can represent the optical characteristics of the illumination that include, but not limited to, numerical aperture settings, illumination sigma (o) settings as well as any particular illumination shape (e.g., off-axis radiation shape such as annular, quadrupole, dipole, etc.), where σ (or sigma) is outer radial extent of the illuminator.

A projection optics model 210 represents optical characteristics (including changes to the radiation intensity distribution and/or the phase distribution caused by the projection optics) of the projection optics. The projection optics model 210 can represent the optical characteristics of the projection optics, including aberration, distortion, one or more refractive indexes, one or more physical sizes, one or more physical dimensions, etc.

The patterning device/design layout model module 220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 230 can be simulated from the source model 200, the projection optics model 210 and the patterning device/design layout model module 220. An aerial image (AI) is the radiation intensity distribution at substrate level. Optical properties of the lithographic projection apparatus (e.g., properties of the illumination, the patterning device, and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 250 can be simulated from the aerial image 230 using a resist model 240. The resist model can be used to calculate the resist image from the aerial image, an example of which can be found in U.S. Pat. No. 8,200,468, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation, and polarization effects—may be captured as part of the projection optics model 210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 260. The post-pattern transfer process model module 260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

Typically, a mask may have thousands or even millions of mask features for which MRC may be performed. The MRC may be performed for each of the mask features. The mask features may be of any of various shapes, e.g., curvilinear mask feature. In some embodiments, the MRC specification may include a minimum critical dimension (CD) of the mask feature that can be manufactured, a minimum curvature of mask feature that can be manufactured, a minimum area of a mask feature, a minimum space between two features, or other geometric properties associated with a mask feature. An MRC violation may occur when the geometric properties of the mask feature do not satisfy the constraints specified in the MRC. For example, an MRC violation may occur when the area of the mask feature is lesser than the minimum area specified in the MRC. In another example, the MRC violation may occur when the space between two mask features is lesser than the minimum space specified in the MRC.

Similarly, a process related metric such as the EPE, which is representative of a shift or change in position of a feature or a portion thereof in the resist from an intended position of that feature in a target layout, may occur due to various reasons, including incorrect geometry of features (e.g., size, shape, position in the mask pattern, etc.) of the mask pattern. Similarly, another process related metric such as SRAF printing, which causes certain features in the mask pattern (e.g., an SRAF) that are not intended to be printed on the substrate to be printed, may occur due to incorrect geometry of features (e.g., when a size of SRAF is greater than a threshold size). The following paragraphs describe configuring a prediction model to minimize the MRC violations or patterning process related metrics (e.g., EPE, SRAF printing, etc.) in predicting (e.g., generate) a mask image from a target image.

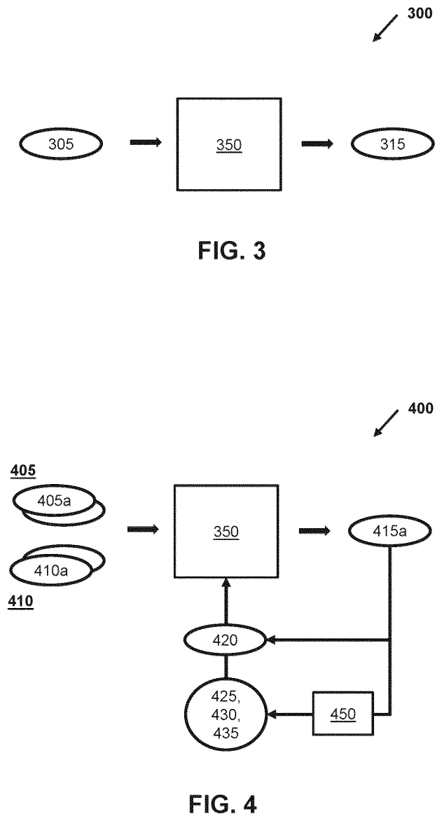

FIG. 3 is a block diagram of a system 300 for generating a mask pattern from a target layout using a prediction model, consistent with various embodiments. A target image 305 is input to a mask generator 350, which generates a mask image 315 of a mask pattern. The mask pattern may have a number of mask features. The mask features may be of any of various shapes, e.g., curvilinear mask feature. In some embodiments, the mask generator 350 is configured to generate the mask pattern such that the MRC violations and at least one of lithographic process metrics such as EPE or SRAF printing is minimized or eliminated.

The target image 305 may include a target layout to be printed on a substrate. The target layout includes a number of features and is generally defined as a pre-OPC design layout which can be provided in a standardized digital file format such as GDSII or OASIS or other file format.

The mask generator 350 may be implemented as a prediction model, such as an ML model (e.g., a neural network), a statistical model, an analytics model, a rule-based model, or any other empirical model. In some embodiments, the mask generator 350 is implemented as a neural network. As an example, neural networks may be based on a large collection of neural units (or artificial neurons). Neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function which combines the values of all its inputs together. In some embodiments, each connection (or the neural unit itself) may have a threshold function such that the signal must surpass the threshold before it propagates to other neural units. These neural network systems may be self-learning and trained, rather than explicitly programmed, and can perform significantly better in certain areas of problem solving, as compared to traditional computer programs. In some embodiments, neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for neural networks may be more free-flowing, with connections interacting in a more chaotic and complex fashion.

The mask generator 350 is configured as an MRC aware or process aware mask generator, that is, a mask generator 350 which generates the mask pattern such that the MRC violations and at least one of lithographic process metrics such as EPE or SRAF printing is minimized or eliminated. A mask having the generated mask pattern may be manufactured using the predicted mask image 315, and may be used in a patterning step to print patterns corresponding to the target image 305 on a substrate via a lithographic process. The process of training the mask generator 350 to generate the mask image 315 is described at least with reference to FIGS. 4-8 below.

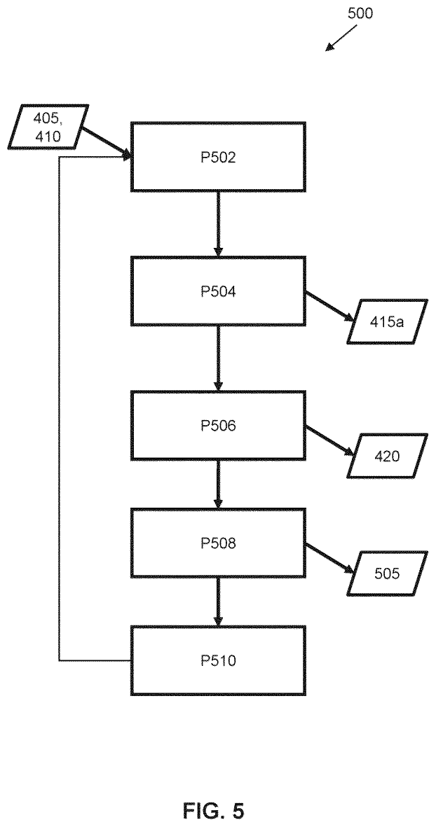

FIG. 4 is a block diagram of a system 400 for training the mask generator 350 as an MRC aware or process aware mask generator, consistent with various embodiments. FIG. 5 is a flow diagram of a method 500 for training the mask generator 350 as an MRC aware or process aware mask generator, consistent with various embodiments. At process P502, a set of target images 405 and a set of reference images 410 are input to the mask generator 350. A target image 405a of the set of images 405 may be an image of a target layout to be printed on a substrate. A reference image 410a of the set of reference images 410 may be an image of OPC mask corresponding to the target layout of the target image 405a. The set of reference images 410 may act as ground truth mask images for training the mask generator 350 to predict a mask image based on the target image. The reference image 410a may be generated in various ways, e.g., using SMO or OPC methods.

At process P504, the mask generator 350 generates a mask image corresponding to a target image. For example, the mask generator 350 generates a mask image 415a representing a mask pattern corresponding to a target layout in the target image 405a. As mentioned above, the mask generator 350 may be implemented as a prediction model, such as a neural network.

At process P506, a loss function component 450 computes a first loss function that is indicative of an image reconstruction loss, which is determined as a difference between the predicted mask image and a reference image. For example, the first loss function 420 may include the image reconstruction loss 420, which may be determined as a difference between the predicted mask image 315 and the reference image 410a.

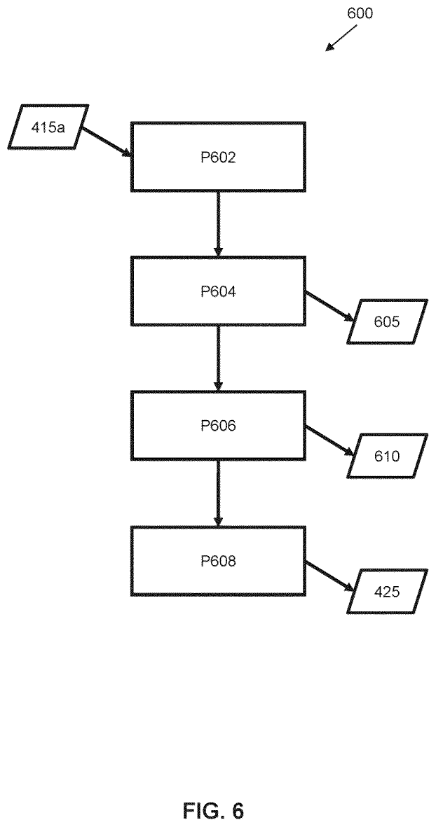

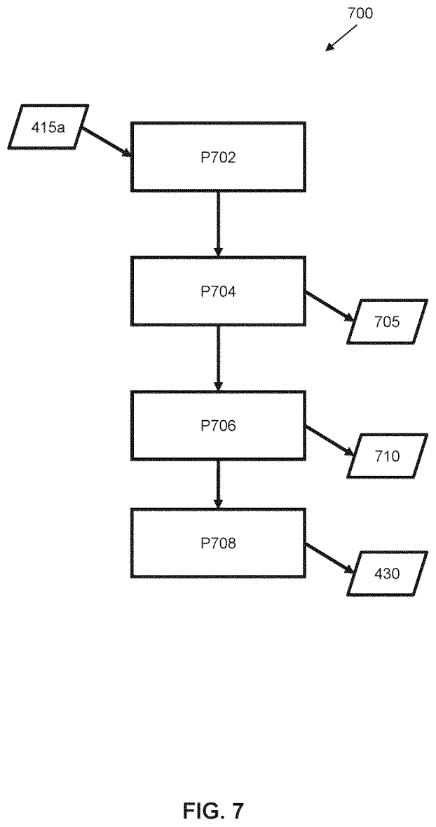

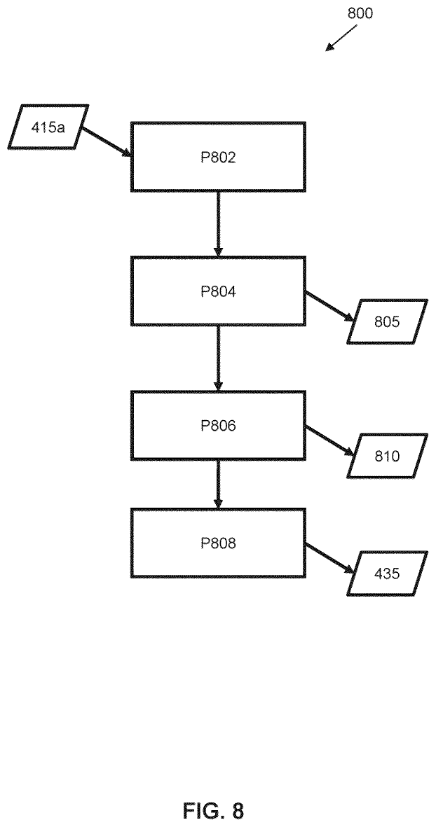

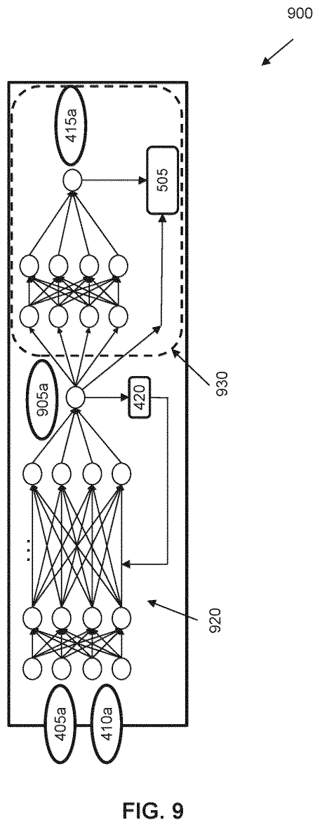

At process P508, the loss function component 450 computes a second loss function 505 that is indicative of at least one of an MRC evaluation of the predicted mask image or an evaluation of a simulated image of the predicted mask image. For example, the second loss function 505 includes an MRC loss 425 or MRC cost 425 that is indicative of an MRC violation of a mask feature of the mask pattern, which may be determined based on an MRC evaluation of the predicted mask image 415a, as described at least with reference to FIG. 6. In another example, the second loss function 505 includes a first simulation cost or a first simulation loss 430 that is indicative of a process metric (e.g., EPE), which may be determined based on a difference between simulated images (e.g., an aerial image, a resist image, or an etch image) of the predicted mask image 415a and the reference image 410a, described at least with reference to FIG. 7. In yet another example, the second loss function 505 includes a second simulation cost or a second simulation loss 435 that is indicative of a process metric (e.g., SRAF printing), which may be determined based on pixel values of a simulated image (e.g., an aerial image, a resist image, or an etch image) of the predicted mask image 415a and a threshold value, as described at least with reference to FIG. 8.

At process P510, the mask generator 350 may be modified or updated based the first loss function and the second loss function. For example, the configuration of the mask generator 350 may be updated to reduce the first loss function 420 and the second loss function 505. The first loss function 420 may include the image reconstruction loss 420. The second loss function 505 may include at least one of the MRC loss 425, first simulation loss 430 and second simulation loss 435. In embodiments where the mask generator 350 is a neural network, updating the configurations of the mask generator 350 includes updating the configurations (e.g., weights, biases, or other parameters) of the neural network based on the loss functions. For example, connection weights may be adjusted to reconcile differences between the neural network's prediction (e.g., predicted mask image 415a) and the reference feedback (reference image 410a). In a further use case, one or more neurons (or nodes) of the neural network may require that their respective errors are sent backward through the neural network to them to facilitate the update process (e.g., backpropagation of error). Updates to the connection weights may, for example, be reflective of the magnitude of error (e.g., loss functions) propagated backward after a forward pass has been completed. In this way, for example, the mask generator 350 may be trained to generate better predictions (e.g., mask images).

In some embodiments, the method 500 of training the mask generator 350 is an iterative process in which each iteration includes generating a predicted mask image (e.g., predicted mask image 415a), computing the first loss function (e.g., image reconstruction loss 420) and the second loss function 505 (e.g., MRC loss 425, first simulation loss 430, or second simulation loss 435), determining whether the first and the second loss functions are minimized, updating a configuration of the mask generator 350 to reduce the first loss function 420 and the second loss function 505. The iterations may be performed until a specified condition is satisfied (e.g., a predetermined number of times, until the first and the second loss functions are minimized, or another condition).

After the training method 500 is completed, the mask generator 350 is considered to be trained as MRC aware or process aware mask generator, which may be used to generate or predict a mask image representing a mask pattern in which the MRC violations and process metrics such as EPE, SRAF printing are minimized or eliminated, as described at least with reference to FIG. 3 above.

FIG. 6 is a flow diagram of a method 600 for determining an MRC loss, consistent with various embodiments. In some embodiments, the method 600 may be executed as part of process P506 of method 500. At process P602, an image is input to the loss function component 450. For example, the predicted mask image 315 is input to the loss function component 450.

At process P604, the loss function component 450 performs an MRC of the predicted mask image 415a to identify MRC violations 605. In some embodiments, performing an MRC evaluation may involve determining whether geometric properties of a mask feature in the mask pattern complies with the MRC specification. For example, performing MRC may involve determining whether a size of a mask feature is greater than a minimum size specified in the MRC specification. If the size is lesser than the minimum size, then the loss function component may identify an MRC violation. The loss function component 450 may process a plurality of mask features of the mask pattern and identify the MRC violations 605.

At process P606, the loss function component 450 may assign a violation score 610 to each of the MRC violations 605. The violation score 610 may be determined in a number of ways. In some embodiments, the violation score 610 may be determined as a function of the MRC violations 605. For example, the greater the magnitude of the MRC violation, the greater may be the violation score 610.

At process P608, the loss function component 450 may determine the MRC loss 425 as a function of the violation score 610. The MRC loss 425 may be determined in a number of ways. For example, the MRC loss 425 may be determined as a value between 0 and 1, and the greater the violation score 610, the greater may be the MRC loss 425.

FIG. 7 is a flow diagram of a method 700 for determining a first simulation loss, consistent with various embodiments. In some embodiments, the method 700 may be implemented as part of process P508 of method 500. In some embodiments, the first simulation loss 430 is indicative of a process metric, such as EPE.

At process P702, an image is input to the loss function component 450. For example, the predicted mask image 415a is input to the loss function component 450.

At process P704, the loss function component 450 simulates a first image 705 from the predicted mask image 415a. The first simulated image 705 may be an aerial image, a resist image or an etch image. In some embodiments, the first simulated image 705 is an aerial image. The first simulated image 705 may be generated in various ways. For example, the first simulated image 705 may be generated using the process or components as described at least with reference to FIG. 2. In some embodiments, the predicted mask image 415a may be up sampled to increase a resolution of the predicted mask image 415a. Additionally, in some embodiments, the predicted mask image 415a may be a continuous transmission mask (CTM) image and may be binarized to generate a binarized mask image.

At process P706, the loss function component 450 simulates a second image 710 from the reference image 410a. The second simulated image 710 may be an aerial image, a resist image or an etch image. In some embodiments, the second simulated image 710 is an aerial image. In some embodiments, the second simulated image 710 may be simulated based on the same conditions or constraints used while generating the first simulated image 705.

At process P708, the loss function component 450 determines the first simulation loss 430 as a function of the difference between the first simulated image 705 and the second simulated image 710. By obtaining the difference between the first simulated image 705 and the second simulated image 710, the loss function component 450 may determine any EPE of a mask feature in the predicted mask image 415a based on the ground truth mask image 410a. In some embodiments, the loss function component 450 may perform the comparison of the simulated images in a region near (e.g., within a specified proximity of) a target feature (e.g., features that are intended to be printed on a substrate). For example, the loss function component 450 may use a fixed filter (e.g., transmission cross coefficient (TCC) kernel) to identify a region near a target feature in the simulated images. In some embodiments, the differences between the simulated images near the target features are weighted more than the differences between the simulated images away from the target features.

FIG. 8 is a flow diagram of a method 800 for determining a second simulation loss, consistent with various embodiments. In some embodiments, the method 800 may be implemented as part of process P508 of method 500. In some embodiments, the second simulation loss 435 is indicative of a process metric, such as SRAF printing.

At process P802, an image is input to the loss function component 450. For example, the predicted mask image 415a is input to the loss function component 450.

At process P804, the loss function component 450 simulates a third image 805 from the predicted mask image 415a. The third simulated image 805 may be an aerial image, a resist image or an etch image. In some embodiments, the third simulated image 805 is an aerial image. The third simulated image 805 may be generated in various ways. For example, the third simulated image 805 may be generated using the process or components as described at least with reference to FIG. 2. In some embodiments, the predicted mask image 415a may be up sampled to increase a resolution of the predicted mask image 415a. Additionally, in some embodiments, the predicted mask image 415a may be a CTM image and may be binarized to generate a binarized mask image.

At process P806, the loss function component 450 compares pixel values of the third simulated image 805 to a threshold value and computes a score 810 as a function of those pixel values exceeding the threshold value. In some embodiments, the loss function component 450 may use a fixed filter (e.g., TCC kernel) to identify a region far from (e.g., outside of a specified proximity of) a target feature (e.g., features that are intended to be printed on a substrate) in the simulated images, and performs the comparison in the identified regions. In some embodiments, by performing the comparison in regions far from the target feature, the loss function component 450 may identify those of the features in the mask pattern that are not intended to be printed on the substrate (e.g., SRAF). In some embodiments, by performing the comparison in regions far from the target feature and by determining pixel values that exceed a threshold value, the loss function component 450 may identify those of the features in the mask pattern that are greater than a predetermined size, thus causing them to be printed on the substrate, and penalize those features by assigning an appropriate score. In some embodiments, portions of the third simulated image 805 that exceed the threshold value far from the target features is weighted more than those portions that exceed the threshold value near the target features.

The threshold value may be obtained in a number of ways. For example, the threshold value may be obtained via user input. In another example, the threshold value may be obtained by simulating an image from the reference image 410a (e.g., by simulating an aerial image from a ground truth mask image and obtaining a threshold score from the simulated image).

At process P808, the loss function component 450 may determine the second simulation loss 435 as a function of the score. The second simulation loss 435 may be determined in a number of ways. For example, the second simulation loss 435 may be determined as a value between 0 and 1, and greater the score 810 greater may be the second simulation loss 435.

FIG. 9 shows an example neural network 900 used to implement the mask generator 350, consistent with various embodiments. The neural network may include an input layer, an output layer, and one or more intermediate or hidden layers. In some embodiments, the one or more neural networks may be and/or include deep neural networks (e.g., neural networks that have one or more intermediate or hidden layers between the input and output layers). As an example, the one or more neural networks may be based on a large collection of neural units (or artificial neurons). As described above at least with reference to FIGS. 4 and 5, in training the neural network to generate a predicted mask image (e.g., predicted mask image 415a), the configuration of the neural network may be updated to minimize the first loss function 420 and the second loss function 505. The neural network may be updated in a number of ways. For example, the configuration (e.g., weights, biases, or other parameters) of the neural network may be updated for the entire neural network based on both the loss functions. In another example, as illustrated in neural network 900 of FIG. 9, the configuration of a first portion 920 of the neural network 900 may be updated to reduce or minimize the first loss function 420, and a configuration of a second portion 930 of the neural network 900 may be updated to reduce or minimize the second loss function 505. That is, in some embodiments, a first portion 920 of the neural network 900 may be trained (based on the first loss function 420) to generate an intermediate mask image 905a from a target image 405a that is faithful to a reference image 410a, and a second portion 930 of the neural network 900 may be trained (based on the second loss function 505) to generate a predicted mask image 415a from the intermediate mask image 905a such that the MRC violations and at least one of the process metrics (e.g., EPE, SRAF printing, etc.) is minimized or eliminated in the predicted mask image 415a.

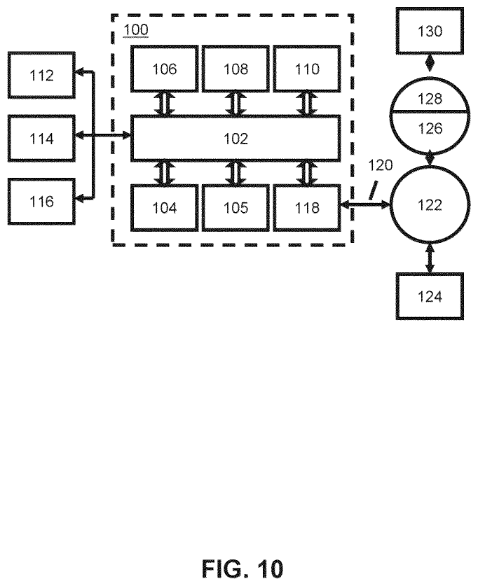

FIG. 10 is a block diagram that illustrates a computer system 100 which can assist in implementing the optimization methods and flows disclosed herein. The computer system 100 may be used to implement any of the entities, components, modules, or services depicted in the examples of the figures (and any other entities, components, modules, or services described in this specification). The computer system 100 may be programmed to execute computer program instructions to perform functions, methods, flows, or services (e.g., of any of the entities, components, or modules) described herein. The computer system 100 may be programmed to execute computer program instructions by at least one of software, hardware, or firmware.

Computer system 100 includes a bus 102 or other communication mechanism for communicating information, and a processor 104 (or multiple processors 104 and 105) coupled with bus 102 for processing information. Computer system 100 also includes a main memory 106, such as a random-access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102.

Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic, or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic, or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

Embodiments of the present disclosure can be further described by the following clauses.

1. A non-transitory computer-readable medium having instructions that, when executed by a computer, cause the computer to execute a method for training a machine learning model to generate a mask pattern to be used for printing a target layout on a substrate, the method comprising:
inputting a target image to the machine learning model, the target image associated with a target layout to be printed on a substrate, wherein the machine learning model is configured to receive a reference image, the reference image corresponding to an optical proximity correction (OPC) mask image of the target image;
generating, using the neural network, a predicted mask image representing a mask pattern to be used for printing the target layout on a substrate;
computing a loss function that is indicative of (a) a difference between the predicted mask image and the reference image, and (b) at least one of an MRC evaluation of the predicted mask image or an evaluation of a first simulated image of the predicted mask image; and
modifying the machine learning model based on the loss function.

2. The computer-readable medium of clause 1, wherein computing the loss function that is indicative of the MRC evaluation of the predicted mask image includes:
computing a mask rule check (MRC) cost by performing the MRC evaluation of the predicted mask image, the MRC cost indicative of an MRC violation.

3. The computer-readable medium of clause 2, wherein the MRC violation comprises a violation of at least one of a critical dimension (CD), a width, an area of a feature in the mask pattern.

4. The computer-readable medium of clause 2, wherein performing the MRC evaluation includes:
assigning a violation score to portions of the mask pattern where the MRC violation occurs; and
determining the MRC cost based on the violation score.

5. The computer-readable medium of clause 1, wherein computing the loss function that is indicative of the evaluation of the first simulated image of the predicted mask image includes:
generating the first simulated image based on the predicted mask image.

6. The computer-readable medium of clause 5, wherein the first simulated image is at least one of an aerial image, a resist image or an etch image.

7. The computer-readable medium of clause 5, wherein computing the loss function includes:
computing a simulation cost that is indicative of a difference between the first simulated image and a second simulated image of the reference image.

8. The computer-readable medium of clause 7, wherein computing the simulation cost includes:
identifying a region in the first simulated image and the second simulated image within a specified proximity of a feature to be printed on the substrate; and
computing the simulation cost that is indicative of a difference between the first simulated image and the second simulated image within the region.

9. The computer-readable medium of clause 5, wherein computing the loss function includes:
computing a score that is indicative of a pixel value of each pixel of the first simulated image exceeding a threshold value; and
computing a simulation cost based on the score.

10. The computer-readable medium of clause 9, wherein the simulation cost is determined based on the scores associated with pixels that are outside a specified proximity of a feature in the first simulated image to be printed on the substrate.

11. The computer-readable medium of clause 9, wherein the threshold value is determined based on pixel values of a second simulated image of the reference image.

12. The computer-readable medium of clause 5, wherein the first simulated image is computed using a fixed filter.

13. The computer-readable medium of clause 12, wherein the fixed filter is generated based on a transmission cross coefficient kernel.

14. The computer-readable medium of clause 5, wherein generating the first simulated image includes:
increasing a resolution of the predicted mask image to generate the first simulated image.

15. The computer-readable medium of clause 14, wherein the predicted mask image is a continuous transmission mask (CTM) image, and wherein the method further comprises:
generating a binarized image of the CTM image.

16. The computer-readable medium of clause 1, wherein modifying the neural network based on the loss function includes:
modifying parameters of the machine learning model until the loss function is minimized.

17. The computer-readable medium of clause 1, wherein the machine learning network comprises a neural network, and wherein modifying the machine learning model based on the loss function includes:
modifying parameters of a first portion of the neural network until the loss function that is indicative of the difference between the predicted mask image and the reference image is minimized; and
modifying parameters of a second portion of the neural network until the loss function that is indicative of at least one of an MRC evaluation of the predicted mask image or the evaluation of the first simulated image of the predicted mask image is minimized.

18. The computer-readable medium of clause 1 further comprising:
inputting a first target image having a first target layout to be printed on a first substrate to the neural network; and
generating, using the neural network, a first predicted mask image representing a first mask pattern to be used for printing the first target layout on the first substrate.

19. The computer-readable medium of clause 18 further comprising:
generating, using the first predicted mask image, a mask having the first mask pattern.

20. The computer-readable medium of clause 19 further comprising:
performing a patterning step using the first mask to print patterns corresponding to the first target layout on the first substrate via a lithographic process.

21. A non-transitory computer-readable medium having instructions that, when executed by a computer, cause the computer to execute a method for training a machine learning model to generate a mask image to be used for printing a target layout on a substrate, the method comprising:
inputting a set of target images and a set of reference images as training data to a neural network, wherein a target image of the set of target images includes a target layout to be printed on a substrate, and wherein a reference image of the set of reference images corresponds to an optical proximity correction (OPC) mask image of the target image; and
training, based on the training data, the machine learning model to generate a predicted mask image such that a loss function that is indicative of (a) a difference between the predicted mask image and the reference image, and (b) an MRC cost associated with an MRC evaluation of the predicted mask image is minimized, wherein the predicted mask image represents a mask pattern to be used for printing the target layout on the substrate.

22. The computer-readable medium of clause 21, wherein training the machine learning model includes:
performing the MRC evaluation of the predicted mask image to determine an MRC violation; and
computing the MRC cost based on the MRC violation.

23. The computer-readable medium of clause 22, wherein the MRC violation comprises a violation of at least one of a critical dimension (CD), a width, an area of a feature in the mask pattern.

24. The computer-readable medium of clause 22, wherein computing the MRC cost includes:
assigning a violation score to portions of the mask pattern where the MRC violation occurs; and
determining the MRC cost based on the violation score.

25. The computer-readable medium of clause 21, wherein the machine learning model comprises a neural network, and wherein training the machine learning model includes:
modifying parameters of the neural network until the loss function is minimized.

26. The computer-readable medium of clause 25, wherein modifying the neural network based on the loss function includes:
modifying parameters of a first portion of the neural network until the loss function that is indicative of the difference between the predicted mask image and the reference image is minimized; and
modifying parameters of a second portion of the neural network until the loss function that is indicative of the MRC cost is minimized.

27. The computer-readable medium of clause 21 further comprising:
inputting a first target image having a first target layout to be printed on a first substrate to the neural network; and
generating, using the neural network, a first predicted mask image representing a first mask pattern to be used for printing the first target layout on the first substrate.

28. The computer-readable medium of clause 27 further comprising:
generating, using the first predicted mask image, a mask having the first mask pattern.

29. The computer-readable medium of clause 28 further comprising:
performing a patterning step using the first mask to print patterns corresponding to the first target layout on the first substrate via a lithographic process.

30. A non-transitory computer-readable medium having instructions that, when executed by a computer, cause the computer to execute a method for training a machine learning model to generate a mask image to be used for printing a target layout on a substrate, the method comprising:
inputting a set of target images and a set of reference images as training data to a neural network, wherein a target image of the set of target images includes a target layout to be printed on a substrate, and wherein a reference image of the set of reference images corresponds to an optical proximity correction (OPC) mask image of the target image; and
training, based on the training data, the machine learning model to generate a predicted mask image such that a loss function that is indicative of (a) a difference between the predicted mask image and the reference image, and (b) a simulation cost associated with a first simulated image of the predicted mask image is minimized.

31. The computer-readable medium of clause 30, wherein the first simulated image is at least one of an aerial image, a resist image or an etch image.

32. The computer-readable medium of clause 30, wherein training the machine learning model includes:
generating the first simulated image based on the predicted mask image; and
computing the simulation cost associated with the first simulated image.

33. The computer-readable medium of clause 30, wherein computing the simulation cost includes:
computing the simulation cost based on a difference between the first simulated image and a second simulated image of the reference image.

34. The computer-readable medium of clause 33, wherein computing the simulation cost includes:
identifying a region in the first simulated image and the second simulated image within a specified proximity of a feature to be printed on the substrate; and
computing the simulation cost that is indicative of a difference between the first simulated image and the second simulated image within the region.

35. The computer-readable medium of clause 32, wherein computing the simulation cost includes:
computing a score that is indicative of a pixel value of each pixel of the first simulated image exceeding a threshold value; and
computing the simulation cost based on the score.

36. The computer-readable medium of clause 35, wherein the simulation cost is determined based on the scores associated with pixels that are outside a specified proximity of a feature in the first simulated image to be printed on the substrate.

37. The computer-readable medium of clause 35, wherein the threshold value is determined based on pixel values of a second simulated image of the reference image.

38. The computer-readable medium of clause 32, wherein the first simulated image is computed using a fixed filter.

39. The computer-readable medium of clause 38, wherein the fixed filter is generated based on a transmission cross coefficient kernel.

40. The computer-readable medium of clause 32, wherein generating the first simulated image includes:
increasing a resolution of the predicted mask image to generate the first simulated image.

41. The computer-readable medium of clause 40, wherein the predicted mask image is a continuous transmission mask (CTM) image, and wherein the method further comprises:
generating a binarized image of the CTM image.

42. A method for training a machine learning model to generate a mask pattern to be used for printing a target layout on a substrate, the method comprising:
inputting a target image to a neural network, the target image associated with a target layout to be printed on a substrate, wherein the machine learning model is configured to receive a reference image, the reference image corresponding to an optical proximity correction (OPC) mask image of the target image;
generating, using the neural network, a predicted mask image representing a mask pattern to be used for printing the target layout on a substrate;
computing a loss function that is indicative of (a) a difference between the predicted mask image and the reference image, and (b) at least one of an MRC evaluation of the predicted mask image or an evaluation of a first simulated image of the predicted mask image; and
modifying the machine learning model based on the loss function.

43. An apparatus for training a machine learning model to generate a mask pattern to be used for printing a target layout on a substrate, the apparatus comprising:
a memory storing a set of instructions; and
a processor configured to execute the set of instructions to cause the apparatus to perform a method of:
   inputting a target image to a neural network, the target image associated with a target layout to be printed on a substrate, wherein the machine learning model is configured to receive a reference image, the reference image corresponding to an optical proximity correction (OPC) mask image of the target image;
   generating, using the neural network, a predicted mask image representing a mask pattern to be used for printing the target layout on a substrate;
   computing a loss function that is indicative of (a) a difference between the predicted mask image and the reference image, and (b) at least one of an MRC evaluation of the predicted mask image or an evaluation of a first simulated image of the predicted mask image; and
   modifying the machine learning model based on the loss function.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions, and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A non-transitory computer-readable medium having instructions that, when executed by a computer system, are configured to cause the computer system to at least:
input a target image to a neural network, the target image associated with a target layout to be printed on a substrate, wherein a machine learning model is configured to receive a reference image, the reference image corresponding to an optical proximity correction (OPC) mask image of the target image;
generate, using the machine learning model, a predicted mask image representing a mask pattern to be used for printing the target layout on a substrate;
compute a loss function that is indicative of (a) a difference between the predicted mask image and the reference image, and (b) an MRC evaluation of the predicted mask image or an evaluation of a first simulated image of the predicted mask image; and
modify the machine learning model based on the loss function.

2. The computer-readable medium of claim 1, wherein the instructions configured to cause the computer system to compute the loss function are configured to cause the computer system to compute the loss function that is indicative of the MRC evaluation of the predicted mask image and to compute a mask rule check (MRC) cost by performance of the MRC evaluation of the predicted mask image, the MRC cost indicative of an MRC violation.

3. The computer-readable medium of claim 2, wherein the MRC violation comprises a violation of at least one selected from: a critical dimension (CD), a width, or an area of a feature in the mask pattern, and
wherein the instructions configured to cause the computer system to perform the MRC evaluation are further configured to cause the computer system to:
assign a violation score to portions of the mask pattern where the MRC violation occurs; and
determine the MRC cost based on the violation score.

4. The computer-readable medium of claim 1, wherein the instructions configured to cause the computer system to compute the loss function are configured to cause the computer system to compute the loss function that is indicative of the evaluation of the first simulated image of the predicted mask image and to generate the first simulated image based on the predicted mask image.

5. The computer-readable medium of claim 1, wherein the first simulated image is at least one selected from: an aerial image, a resist image or an etch image.

6. The computer-readable medium of claim 4, wherein the instructions configured to cause the computer system to compute the loss function are configured to cause the computer system to compute a simulation cost that is indicative of a difference between the first simulated image and a second simulated image of the reference image.

7. The computer-readable medium of claim 6, wherein the instructions configured to cause the computer system to compute the simulation cost are configured to cause the computer system to:
identify a region in the first simulated image and the second simulated image within a specified proximity of a feature to be printed on the substrate; and
compute the simulation cost that is indicative of a difference between the first simulated image and the second simulated image within the region.

8. The computer-readable medium of claim 4, wherein the instructions configured to cause the computer system to compute the loss function are configured to cause the computer system to:
compute a score that is indicative of a pixel value of each pixel of the first simulated image exceeding a threshold value; and
compute a simulation cost based on the score, wherein the simulation cost is determined based on the scores associated with pixels that are outside a specified proximity of a feature in the first simulated image to be printed on the substrate.

9. The computer-readable medium of claim 5, wherein the first simulated image is computed using a fixed filter.

10. The computer-readable medium of claim 9, wherein the fixed filter is generated based on a transmission cross coefficient kernel.

11. The computer-readable medium of claim 5, wherein the instructions configured to cause the computer system to generate the first simulated image are configured to cause the computer system to increase a resolution of the predicted mask image to generate the first simulated image.

12. The computer-readable medium of claim 11, wherein the predicted mask image is a continuous transmission mask (CTM) image, and wherein the instructions are further configured to cause the computer system to generate a binarized image of the CTM image.

13. The computer-readable medium of claim 1, wherein the machine learning model comprises the neural network, and wherein the instructions configured to cause the computer system to modify the neural network based on the loss function are configured to cause the computer system to:
modify parameters of a first portion of the neural network based on the loss function that is indicative of the difference between the predicted mask image and the reference image; and
modify parameters of a second portion of the neural network based on the loss function that is indicative of an MRC evaluation of the predicted mask image or of an evaluation of the first simulated image of the predicted mask image.

14. The computer-readable medium of claim 1, wherein the instructions are further configured to cause the computer system to:
input a first target image having a first target layout to be printed on a first substrate to the neural network; and
generate, using the neural network, a first predicted mask image representing a first mask pattern to be used for printing the first target layout on the first substrate.

15. The computer-readable medium of claim 14, wherein the instructions are further configured to cause the computer system to generate comprising: generating, using the first predicted mask image, a mask having the first mask pattern.

16. A non-transitory computer-readable medium having instructions therein that, when executed by a computer system, are configured cause the computer system to at least:
input a set of target images and a set of reference images as training data to a neural network, wherein a target image of the set of target images includes a target layout to be printed on a substrate, and wherein a reference image of the set of reference images corresponds to an optical proximity correction (OPC) mask image of the target image; and
train, based on the training data, a machine learning model to generate a predicted mask image for printing on a substrate such that a loss function that is indicative of (a) a difference between the predicted mask image and the reference image, and (b) an MRC cost associated with an MRC evaluation of the predicted mask image is minimized, wherein the predicted mask image represents a mask pattern to be used for printing the target layout on the substrate.

17. The computer-readable medium of claim 16, wherein the instructions configured to cause the computer system to train the machine learning model are further configured to cause the computer system to:
perform the MRC evaluation of the predicted mask image to determine an MRC violation; and
compute the MRC cost based on the MRC violation.

18. The computer-readable medium of claim 16, wherein the instructions are further configured to cause the computer system to:
input a first target image having a first target layout to be printed on a first substrate to a neural network; and
generate, using the neural network, a first predicted mask image representing a first mask pattern to be used for printing the first target layout on the first substrate.

19. A non-transitory computer-readable medium having instructions therein that, when executed by a computer system, are configured cause the computer system to at least:
input a set of target images and a set of reference images as training data to a neural network, wherein a target image of the set of target images includes a target layout to be printed on a substrate, and wherein a reference image of the set of reference images corresponds to an optical proximity correction (OPC) mask image of the target image; and
train, based on the training data, a machine learning model to generate a predicted mask image for printing on a substrate such that a loss function that is indicative of (a) a difference between the predicted mask image and the reference image, and (b) a simulation cost associated with a first simulated image of the predicted mask image is minimized.

20. The computer-readable medium of claim 19, wherein the instructions configured to cause the computer system to train the machine learning model are further configured to cause the computer system to:
generate the first simulated image based on the predicted mask image; and
compute the simulation cost associated with the first simulated image.
